(19) United States
(12) Patent Application Publication
(10) Pub. No.: US 2025/0300568 A1
(43) Pub. Date: Sep. 25, 2025

(54) SYSTEM FOR ACHIEVING A MID VOLTAGE CONNECTION IN AN ACTIVE RECTIFIER WITH A HEAT SINK

(71) Applicant: GE Precision Healthcare LLC, Waukesha, WI (US)

(72) Inventors: Baptiste Salvi, Buc (FR); Nicolas Levilly, Buc (FR); Evguen Tsourkan, Buc (FR)

(21) Appl. No.: 18/610,089

(22) Filed: Mar. 19, 2024

(51) Int. Cl. H02M 7/00; H02M 7/217; H05K 7/20

(52) U.S. Cl. CPC H02M 7/003; H02M 7/217; H05K 7/209

(57) ABSTRACT

Methods and systems are provided for an active rectifier comprising an alternating current (AC) portion on one side of the active rectifier, a direct current (DC) portion on another side of the active rectifier, an insulated gate bipolar transistor (IGBT) portion positioned between the AC portion and the DC portion, and a heat sink positioned below the IGBT portion and between the AC portion and DC portion, the heat sink electrically coupling the AC portion and the DC portion to achieve a reduced inductive path between the AC portion and the DC portion.

### FIELD

Embodiments of the subject matter disclosed herein relate to medical imaging, and more particularly, to x-ray generation.

### BACKGROUND

In various imaging systems, an x-ray source emits an x-ray beam toward a subject or object, such as a patient. After attenuation by the subject, the x-ray beam impinges upon a detector array. An intensity of the attenuated beam radiation received at the detector array depends on upon attenuation of the x-ray beam by the subject. Each detector element of the detector array produces a separate electrical signal which is transmitted to a data processing system for analysis and generation of a medical image. Increasing efficiency of an x-ray generator that operates as the x-ray source may reduce a footprint of the x-ray generator and increase the overall performance of the x-ray generator.

### BRIEF DESCRIPTION

This summary introduces concepts that are described in more detail in the detailed description. It should not be used to identify essential features of the claimed subject matter, nor to limit the scope of the claimed subject matter. In one aspect, a system can include an active rectifier of an x-ray generator, the active rectifier may include an alternating current (AC) portion positioned on one side of the active rectifier, a direct current (DC) portion positioned on another side of the active rectifier, an insulated gate bipolar transistor (IGBT) portion positioned on top of a heat sink that electrically couples the AC portion and the DC portion, the heat sink being positioned below the IGBT portion and between the AC portion and DC portion. In this way, a mid-voltage connection between the AC portion and the DC portion with a lower inductive path that reduces impedance of power signals may be achieved. By integrating the active rectifier in an x-ray generator, the active rectifier may provide stabilized DC output to other components of the x-ray generator and introduce a power factor correction that increases the efficiency of the x-ray generator.

It should be understood that the brief description above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The present disclosure will be better understood from reading the following description of non-limiting embodiments, with reference to the attached drawings, wherein below:

FIG. 1 shows a block schematic diagram of an x-ray generation and detection system;

FIG. 2 shows a first example of a mid-voltage connection achieved via a heat sink;

FIG. 3 shows a second example of a mid-voltage connection achieved via a heat sink;

FIG. 4 shows a circuit schematic diagram of an active rectifier that incorporates disclosed embodiments;

FIG. 5 shows a perspective view of an AC portion of an active rectifier that incorporates disclosed embodiments;

FIG. 6 shows a perspective view of a DC portion of an active rectifier that incorporates the disclosed embodiments;

FIG. 7 shows a profile view of an active rectifier that incorporates disclosed embodiments;

FIG. 8 shows a perspective view of an active rectifier that incorporates disclosed embodiments;

FIG. 9 shows a magnified profile view of an active rectifier that incorporates disclosed embodiments; and

FIG. 10 shows a magnified profile view of a DC side of an active rectifier.

### DETAILED DESCRIPTION

The following description relates to achieving a stabilized DC output voltage from an x-ray generator with an ability for power factor correction. In particular, the following description relates to integrating an active rectifier into the x-ray generator to provide stabilized DC output voltages to other components of the x-ray generator and introduce power factor correction to the x-ray generator. Existing x-ray generators utilize a simple diode bridge to convert AC waveforms from the mains electricity to DC waveforms (e.g., convert an AC to a DC), which does output DC voltage. Although there are many advantages for including a simple diode bridge to convert AC to DC, the simple diode bridge does not provide a stabilized DC output voltage or enable power factor correction.

More specifically, the output DC voltage is variable and fluctuates significantly. Depending on the load and the country wherein the x-ray generator is located and coupled to a power source, the decibels (e.g. the ratio between power values) may vary from 350 V to 750 V. Large variations in decibels affect the volume, the footprint, and the cost of the x-ray generator. In particular, to account for variable DC output voltages, larger components are integrated within the x-ray generator, and thus, the cost and footprint of the x-ray generator are higher. Additionally, existing x-ray generators do not include a power factor correction that increases the electrical efficiency of the x-ray generator. Or rather, the x-ray generator is unable to ensure that the amount of power delivered from the mains electricity is equal to or nearly equal to that of the power withdrawn from the mains electricity. As such, the x-ray generator may be considered electrically inefficient.

Thus, the issues described above may be addressed by integrating an active rectifier into an x-ray generator. The active rectifier may be a front-end converter that is electrically coupled to an inverter and to a transformer assembly of the x-ray generator. The active rectifier of the x-ray generator includes a heat sink that electrically couples an AC portion on one side of the active rectifier to a DC portion on another side of the active rectifier. The active rectifier may further include an IGBT portion that is positioned between the AC portion and DC portion and on top of the heat sink and is electrically coupled to the DC portion. The AC portion may include a plurality of power regions (e.g., three power regions) populated with a plurality of power components wherein each power region corresponds to one phase of an AC network. The DC portion may include a plurality of DC regions (e.g., three DC regions) populated with a plurality of DC components and the IGBT portion may include three IGBT modules wherein each IGBT module may be electrically coupled to one DC region.

A mid path connection is achieved by electrically coupling the AC portion and the DC portion of the active rectifier with the heat sink. By coupling the AC portion and the DC portion in this way, a lowest possible inductive path that reduces nanohenries through the mid path connection may be achieved. Accordingly, radiated emissions and conductive emissions that affect electromagnetic interference (EMI) and electromagnetic compatibility (EMC) are reduced. The configuration of the active rectifier may enable production of a stabilized DC output voltage and enable a power factor correction that enables greater power efficiency of the active rectifier. An active rectifier with a higher efficiency may increase the performance of the x-ray generator. Thus, according to embodiments described herein, a higher performing active rectifier, and thus x-ray generator, is provided.

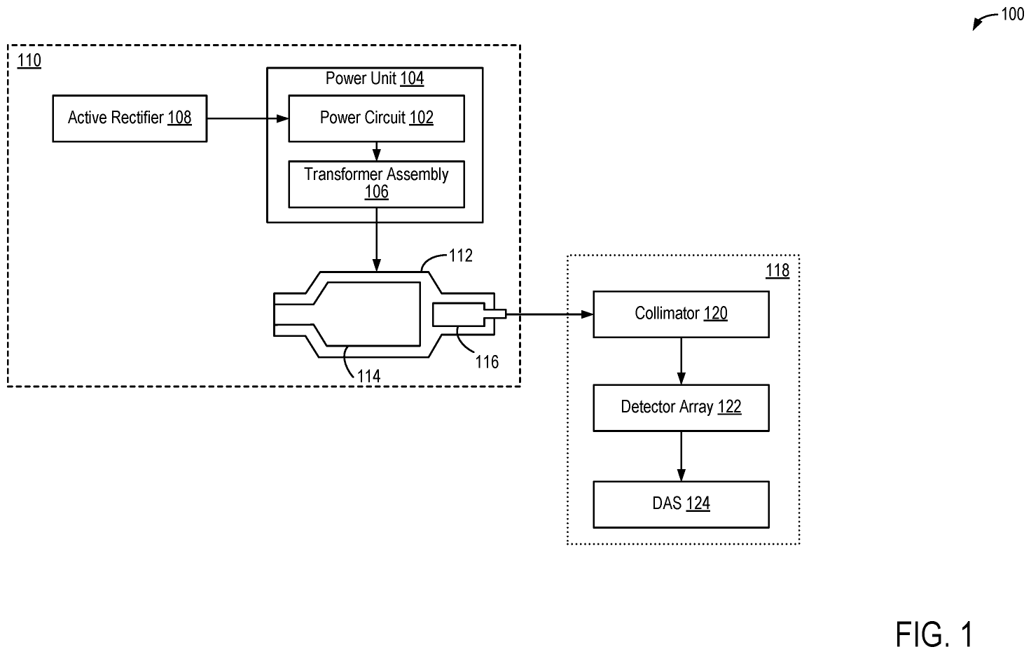

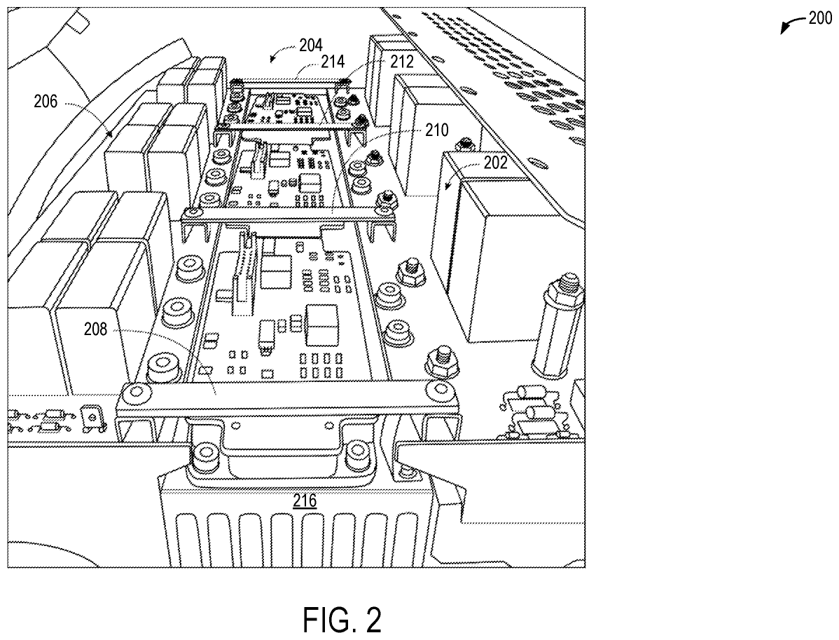

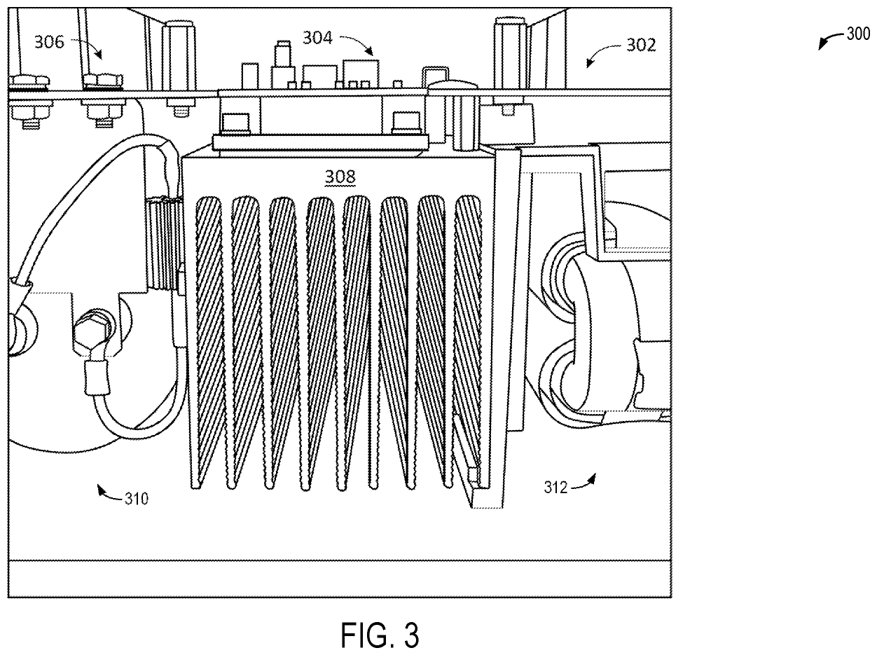

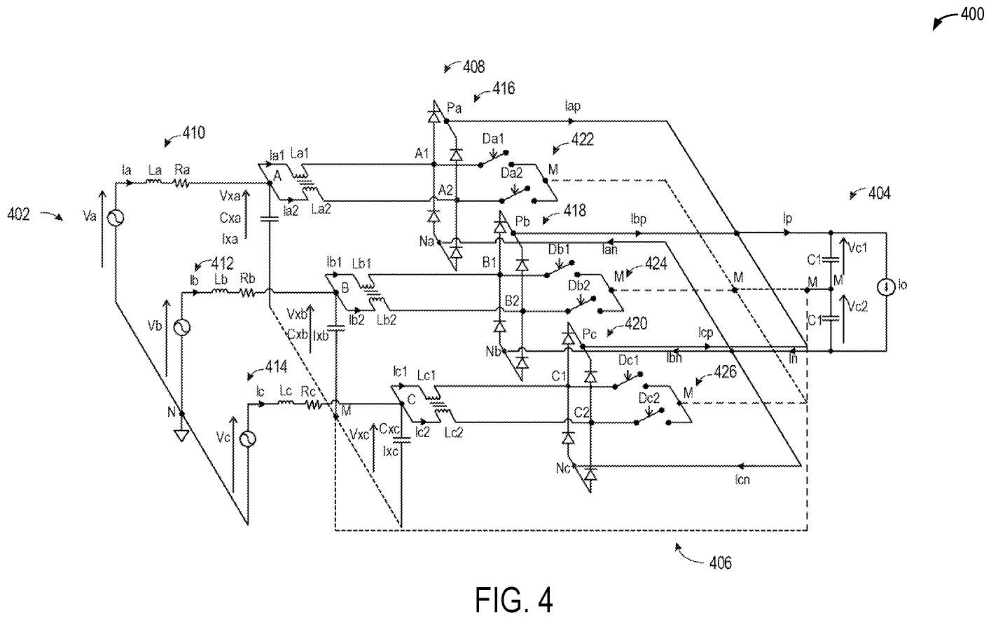

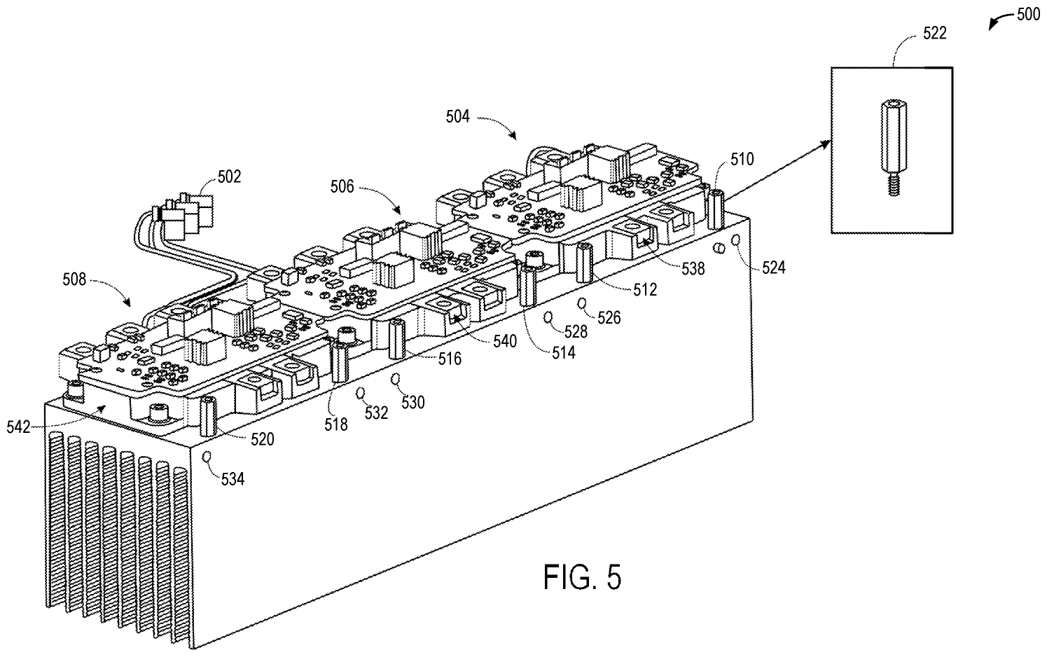

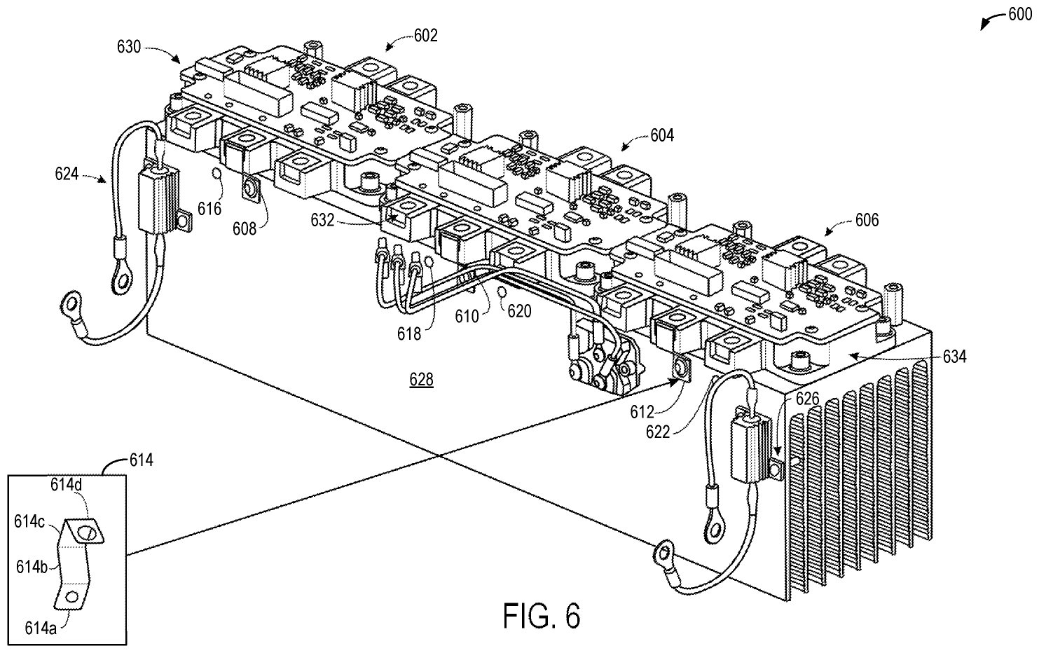

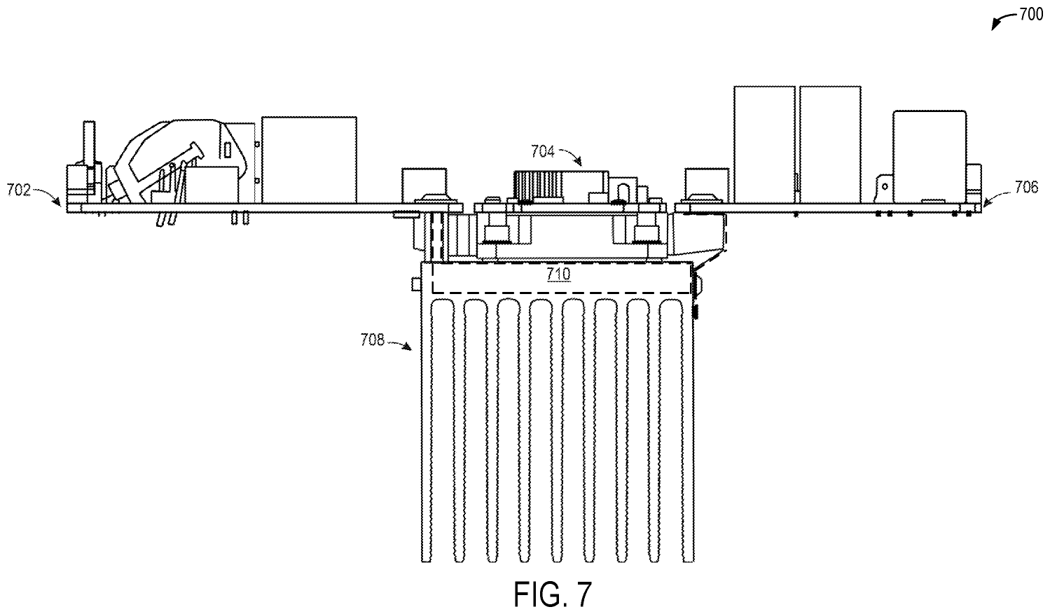

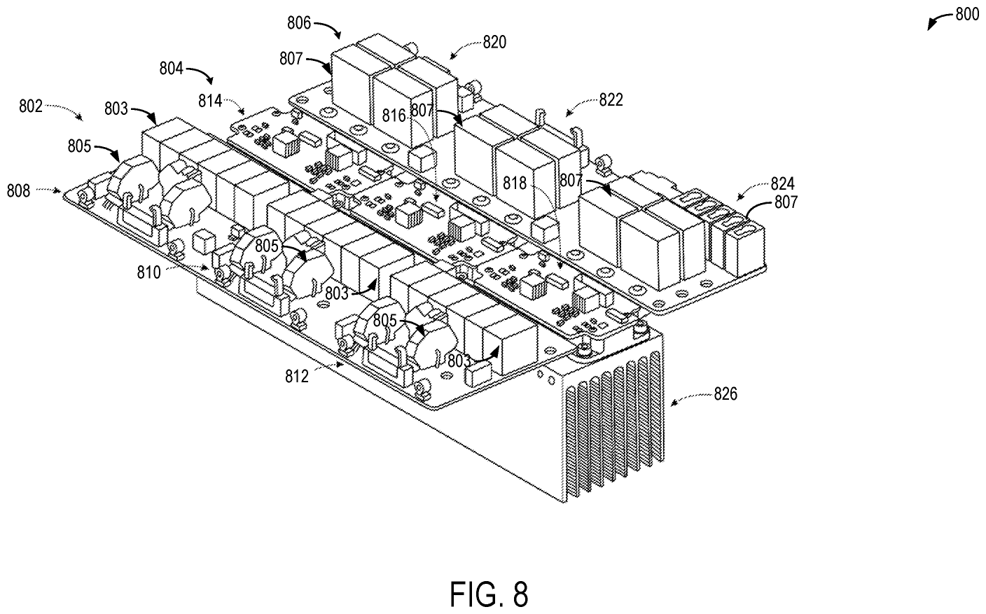

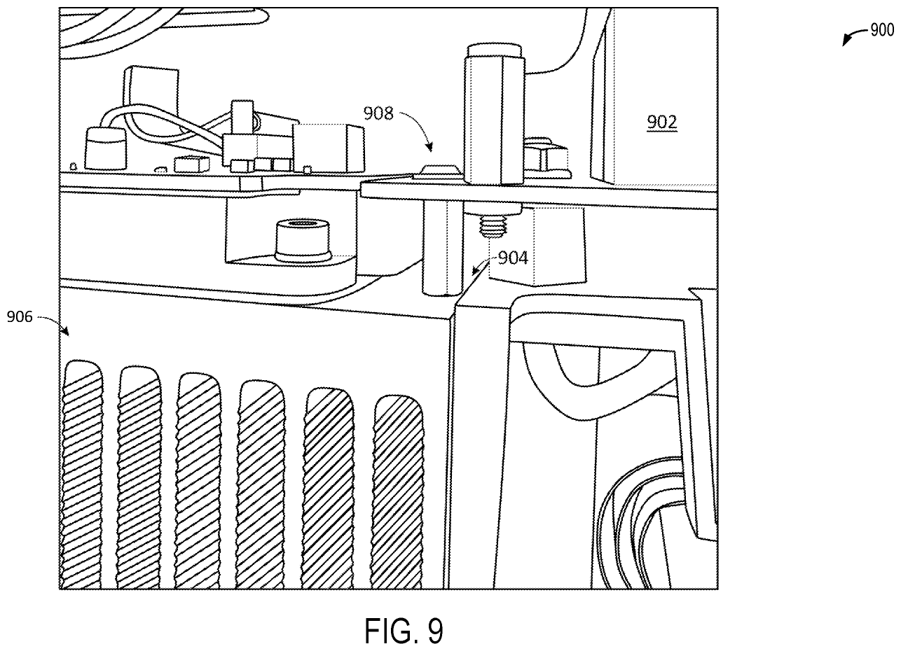

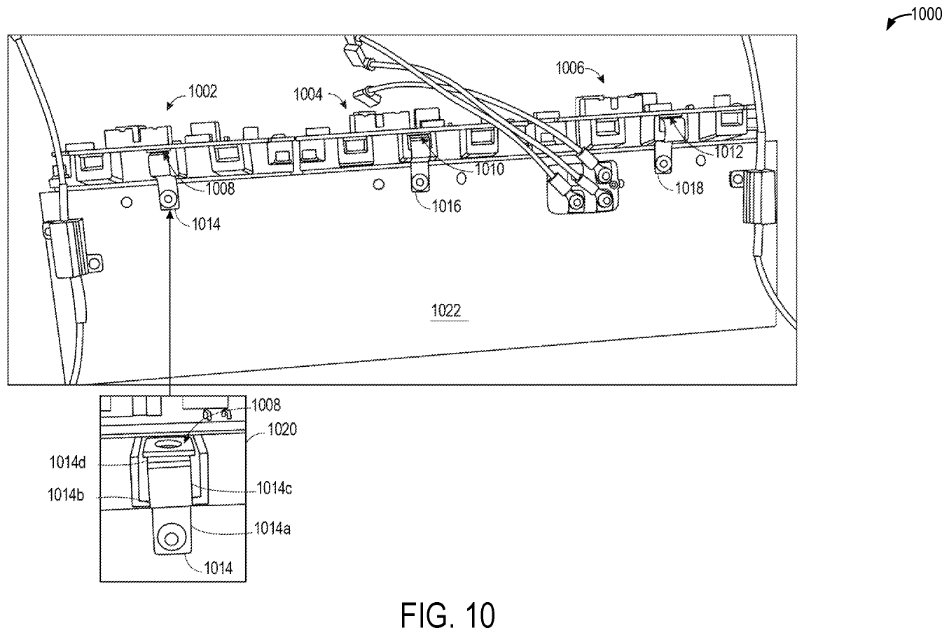

FIG. 1 depicts an x-ray generation and detection system wherein the active rectifier is integrated. FIG. 2 illustrates an active rectifier with a first example of a mid-voltage connection. FIG. 3 illustrates an active rectifier with a second example of a mid-voltage connection. FIG. 4 shows a circuit schematic diagram of an active rectifier according to embodiments of the disclosure. FIG. 5 shows a perspective view of an AC portion and FIG. 6 shows a DC portion of an active rectifier. A profile view of an active rectifier according to the embodiments described herein is shown in FIG. 7. A perspective view of an active rectifier according to the embodiments described herein is shown in FIG. 8. FIG. 9 shows magnified profile view of an active rectifier according to the embodiments described herein. FIG. 10 shows a profile view of a DC side of an active rectifier according to the embodiments described herein.

FIG. 1 illustrates an x-ray generation and detection system 100 configured for medical imaging. Particularly, the x-ray generation and detection system 100 is configured to generate and detect x-rays that may be used to image a subject, such as a patient, an inanimate object such as a phantom, one or more manufactured parts, and/or foreign objects such as dental implants, stents, and/or contrast agents present within the body.

In one embodiment, the x-ray generation and detection system 100 may include an x-ray generator 110 and an x-ray detection system 118. The x-ray generator 110 may include an active rectifier 108 which is electrically coupled to a power unit 104 and configured to supply power to the power unit 104 in addition to an x-ray tube 112. The power unit 104 may include a power circuit 102 that is configured to supply power to a transformer assembly 106. The transformer assembly 106 may be electrically coupled to the x-ray tube 112. The active rectifier 108 may comprise an AC circuit board with three AC circuit board regions on one side of the active rectifier, a DC circuit board with three DC circuit board regions on another side of the active rectifier, a heat sink that is electrically coupled to the AC circuit board on one side of the heat sink and to the DC circuit board on one another side of the heat sink, and three IGBT circuit boards that are positioned on a top surface of the heat sink and positioned between the three AC circuit board regions and the three DC circuit board regions. Embodiments of the active rectifier 108 are described further in FIGS. 2-10. The x-ray detection system 118 may include a collimator 120, a detector array 122, and a data acquisition system (DAS) 124.

The active rectifier 108 may convert an alternating current (AC) high voltage output from a power distribution unit (PDU) to a direct current (DC) high voltage. The power circuit 102 may receive electrical main power from the active rectifier 108. In an example, the power circuit 102 may include a frequency converter which produces a high frequency input power signal to the transformer assembly 106. The power from the power circuit 102 is delivered to the transformer assembly 106 located therein. The transformer assembly 106 may generate the high voltage potentials desired by an x-ray tube 112 to generate x-rays. Particularly, in dual energy (DE) or multiple energy (ME) x-ray applications, the power circuit 102 and the transformer assembly 106 are capable of generating multiple voltage levels across the x-ray tube 112. In this way, high voltage energy of the x-ray tube 112 may be between two or more output energy levels.

The x-ray generation and detection system 100 may further include at least one x-ray tube 112 configured to project a beam of x-ray radiation for use in imaging the subject. Specifically, the x-ray tube 112 is configured to project the x-rays towards a detector array 122 via a collimator 120. Although FIG. 1 depicts a single x-ray tube 112, in certain embodiments, multiple x-ray radiation sources and detectors may be employed to project a plurality of x-rays for acquiring, for example, at different energy levels corresponding to the patient.

The x-ray tube 112 generally includes a cathode 114 and an anode 116. The cathode 114 and anode 116 are arranged in a generally opposing alignment along a longitudinal axis of the x-ray tube 112. The cathode 114 includes an electron-emitting filament that is capable in a conventional manner of emitting electrons. A filament heating current controls the number of electrons boiled off by the filament and thus provides control of the tube current flow. The high voltage potential applied by the power unit 104 causes acceleration of the electrons from the cathode 114 towards the anode 116. The accelerated electrons collide with the anode 116, producing electromagnetic radiation, including x-ray radiation.

The power unit 104 may be configured to receive a DC waveform from the active rectifier 108. In particular, the power circuit 102 may be configured to receive the DC waveform from the active rectifier 108 and convert the DC voltage signal to a higher frequency AC voltage signal. The transformer assembly 106 of the power unit 104 may be configured to receive an AC waveform from the power circuit 102 and condition the AC voltage signal transferred by the power circuit 102 to provide a high voltage DC potential to the x-ray tube 112 where the anode 116 and the cathode 114 usually carry equal voltages of different polarity.

The x-ray tube 112 emits a cone-shaped beam which is collimated to lie within a plane of an X-Y-Z Cartesian coordinate system and generally referred to as an “imaging plane.” The radiation beam passes through an object being imaged, such as the patient or subject. The beam, after being attenuated by the object, impinges upon the detector array 122 comprising radiation detectors. The intensity of the attenuated radiation beam received at the detector array 122 is dependent upon the attenuation of the radiation beam by the object. Each detector element of the array produces a separate electrical signal that is a measurement of the beam attenuation of a ray path between the source and the detector element. The attenuation measurements from all the detector elements are acquired separately to produce a transmission profile.

The detector array 122 further includes a plurality of detector elements that together sense the x-ray beams that pass through the subject (such as a patient) to acquire corresponding projection data. As the x-ray tube 112 and the detector array 122 rotate, the detector array 122 collects data of the attenuated x-ray beams. A collimator 120 comprising a plurality of collimator plates may be positioned on a detection side of the detector elements between the subject and the detector array 122. The collimator 120 is used to manage the x-ray beams by either focusing the x-ray tube 112 into a parallel beam that may be directed onto an area of interest or absorbing and attenuating scattered x-ray beams once they have emerged from the subject.

In certain embodiments, the x-ray generation and detection system 100 may include a data acquisition system (DAS) 124 configured to sample analog data received from the detector elements of the detector array 122 and convert the analog data to digital signals for subsequent processing. The DAS 124 may be further configured to selectively aggregate analog data from a subset of the detector elements. The data sampled and digitized by the DAS 124 is transmitted to a computer or computing device. The data may be used to generate medical images for interventional surgery and other medical applications.

FIG. 2 illustrates an active rectifier 200 with a mid-voltage connection. The active rectifier 200 includes an AC portion 202 with a plurality of power regions, including three power regions, positioned on one side of the active rectifier, each power region corresponding to a different phase of an AC network. The plurality of power regions may be populated with a plurality of power components, such as capacitors, current sensors, power resistors, inductors, and the like. The active rectifier 200 also includes a DC portion 206 with a plurality of DC regions, including three DC regions, positioned on another side of the active rectifier, the side being different than the side wherein the AC portion is positioned and an IGBT portion 204 with three IGBT modules positioned on a heat sink 216 that extends a length of the active rectifier 200. The plurality of DC regions may be populated with a plurality of DC components, such as capacitors, resistors, current sensors, voltage sensors, and the like.

Each IGBT module is positioned between one power region on one side of the active rectifier 200 and one DC region on the other side of the active rectifier 200. The heat sink 216 is electrically coupled to the mid-voltage connection and electrically isolated from the ground chassis of the active rectifier 200. The mid-voltage connection of the active rectifier 200 may comprise a plurality of bars that extend from the AC portion 202 on one side of the active rectifier over the IGBT portion 204 to the DC portion 206 on the other side of the active rectifier. The plurality of bars may be copper or another conductive metal. In particular, the mid-voltage connection may comprise a first bar 208, a second bar 210, a third bar 212, and a fourth bar positioned between the AC portion 202 and the DC portion 206.

The first bar 208 may be positioned between the AC portion 202 and the DC portion 206 on one end of the active rectifier 200 and the fourth bar 214 may be positioned between the AC portion 202 and the DC portion on the other end of the active rectifier 200. The second bar 210 may be positioned in between the two power regions of the AC portion 202 and the two DC regions of the DC portion 206 closest to the end wherein the first bar 208 is located. The third bar 212 may be positioned in between the two power regions of the AC portion 202 and the two DC regions of the DC portion 206 closest to the end wherein the fourth bar 214 is located. A length of the mid-voltage connection is approximately 18 cm with such a mid-voltage connection configuration.

Although the plurality of bars enables the mid-voltage connection between the AC portion 202 and the DC portion 206 and introduces power factor correction to an x-ray generator system, an active rectifier 200 with the mid-voltage connection does not provide a desired level of stability for the DC output voltage. The lack of electrical inefficiency may lead to larger components being used in the x-ray generation and detection system, which in turn increases the footprint and cost of the x-ray generation and detection system, which may be an embodiment of the x-ray generation detection system described in FIG. 1.

FIG. 3 illustrates an active rectifier 300 with a mid-voltage connection, the mid-voltage connection being different than the mid-voltage connection described in FIG. 2. Similar to the active rectifier described in FIG. 2, the active rectifier 300 includes an AC portion 302 with a plurality of power regions populated with a plurality of power components (e.g., three power regions) positioned on one side of the active rectifier, each power region corresponding to a different phase of an AC network. The active rectifier 300 also includes a DC portion 306 with a plurality of power regions populated with a plurality of DC components (e.g., three DC regions) positioned on another side of the active rectifier, the side being different than the side wherein the AC portion is positioned and an IGBT portion 304 with three IGBT modules positioned on a heat sink 308 that extends a length of the active rectifier 300. The active rectifier 300 may further include a DC capacitor 310 positioned below the DC portion 306 and an AC inductor 312 positioned below the AC portion 302.

The heat sink 308 is not electrically coupled to a ground chassis of the active rectifier 300. The mid-voltage connection of the active rectifier 300 may comprise a plurality of standoffs and a plurality of connecting members that electrically couple the AC portion 302 with the heat sink 308 and electrically couple the heat sink 308 with the DC portion 306. The mid-voltage connection of the active rectifier 300 is approximately 12 cm when considering the heat sink. However, the heat sink may be considered negligible. In this case, the mid-voltage connection of the active rectifier is approximately 4 cm. Various embodiments of the active rectifier 300 are described further in FIGS. 4-10.

By using the heat sink as the mid-voltage connection in the active rectifier 300, the active rectifier provides a desired level of stability for the DC output voltage. Additionally, the active rectifier may introduce power factor correction to an x-ray generator system, which may increase the electrical efficiency of the active rectifier and the x-ray generator. As such, smaller components may be used in the x-ray generation and detection system, which in turn decreases the footprint and cost of the x-ray generation and detection system, which may be an embodiment of the x-ray generation and detection system described in FIG. 1.

A circuit schematic diagram of an active rectifier 400 is illustrated in FIG. 4. The circuit schematic diagram of the active rectifier 400 includes an AC portion 402 on one side of the active rectifier 400, a DC portion 404 on another side of the active rectifier, a mid-voltage connection 406 that extends from the AC portion 402 to the DC portion 404, and an IGBT portion 408 that is positioned between the AC portion 402 and the DC portion 404. The AC portion 402 includes a first power region 410, a second power region 412, and a third power region 414. The IGBT portion 408 includes a first IGBT module 416, a second IGBT module 418, and a third IGBT module 420. The DC portion 404 includes a first DC region 422, a second DC region 424, and a third DC region 426.

The AC portion 402 may be electrically coupled to a signal ground at a junction N. A current Iₐ flows from an AC power source with an input voltage Vₐ through the first power region 410 as the current Iₐ flows through an inductor L_{ga} and a resistor R_{ga} of the first power region 410. After flowing through the inductor L_{ga} and the resistor R_{ga}, the current Iₐ flows to a junction A where the current Iₐ splits into Iₐ₁ and Iₐ₂. The current Iₐ₁ flows through an inductor Lₐ₁ that is parallel to an inductor Lₐ₂. The current Iₐ₂ flows through the inductor Lₐ₂. The current Iₐ₁ flows (e.g., output of the inductor Lₐ₁) to a junction A1 and the current Lₐ₂ flows (e.g., output of the inductor Lₐ₂) to a junction A2. The output of the inductor Lₐ₁ and the output of the inductor Lₐ₂ are electrically coupled to respective inputs of the Vienna topology of the first IGBT module 416.

A current I_{b} flows from the AC power source with an input voltage of V_{b} through the second power region 412 as the current I_{b} flows through an inductor L_{gb} and a resistor R_{gb} of the second power region 412. After flowing through the inductor L_{gb} and the resistor R_{gb}, the current I_{b} flows to a junction B where the current I_{b} splits into I_{b1} and I_{b2}. The current I_{b1} flows through an inductor L_{b1} that is parallel to an inductor L_{b2}. The current I_{b2} flows through the inductor L_{b2}. The current I_{b1} flows (e.g., output of the inductor L_{b1}) to a junction B1 and the current I_{b2} flows (e.g., output of the inductor L_{b2}) to a junction B2. The output of the inductor L_{b1} and the output of the inductor L_{b2} are electrically coupled to respective inputs of the Vienna topology of the second IGBT module 418.

A current I_{c} flows from the AC power source with an input voltage of V_{c} through the third power region 414 until the current I_{c} flows through an inductor L_{gc} and a resistor R_{gc} of the third power region 414. After flowing through the inductor L_{gc} and the resistor R_{gc}, the current I_{c} flows to a junction C where the current I_{c} splits into I_{c1} and I_{c2}. The current I_{c} flows through an inductor L_{c1} that is parallel to an inductor L_{c2}. The current I_{c2} flows through the inductor L_{c2}. The current I_{c1} flows (e.g., output of the inductor L_{c1}) to a junction C1 and the current I_{c2} flows (e.g., output of the inductor L_{b2}) to a junction C2. The output of the inductor L_{c1} and the output of the inductor Lᵥ₂ are electrically coupled to respective inputs of the Vienna topology of the third IGBT module 420.

Returning to the junction A, a current Iₓₐ flows with a voltage Vₓₐ through a capacitor Cₓₐ to a mid-connection node M. Returning to the junction B, a current I_{xb} flows with a voltage V_{xb} through a capacitor C_{xb} to a mid-connection node M. Returning to the junction C, a current I_{xc} flows with a voltage V_{xc} through a capacitor C_{xc} to a mid-connection node M. The active rectifier 400 has three AC phases without neutral as input. The mid-connection node M between each of the capacitors Cₓₐ, C_{xb}, and C_{xc} achieves a virtual neutral, which is a line connecting each of the capacitors Cₓₐ, C_{xb}, and C_{xc} (e.g., the mid-voltage connection 406).

The AC portion 402 on one side of the active rectifier 400 is electrically coupled to the DC portion 404 via the mid-connection node M which extends from the AC portion to the DC portion via a heat sink as described herein. The DC portion 404 is electrically coupled to the IGBT portion 408. In this way, the mid-voltage connection 406 is electrically coupled to the outputs of each of the first IGBT module 416, the second IGBT module 418, and the third IGBT module 420 at the mid-connection node M. In particular, the mid-voltage connection 406 is electrically coupled to the outputs of each of the first IGBT module 416, the second IGBT module 418, and the third IGBT module 420 by a capacitor C1 in series with a capacitor C2. There is a voltage V_{C1} at the capacitor C1 and a voltage V_{C2} at the capacitor C2.

Additionally, the mid-voltage connection 406 is electrically coupled to the first IGBT module 416 by a switch Dₐ₁ and a switch Dₐ₂, the switch Dₐ₁ being in parallel with the switch Dₐ₂. The mid-voltage connection 406 is electrically coupled to the second IGBT module 418 by a switch D_{b1} and a switch D_{b2}, the switch D_{b1} being in parallel with the switch D_{b2}. The mid-voltage connection 406 is electrically coupled to the third IGBT module 420 by a switch D_{c1} and a switch D_{c2}, the switch D_{c1} being in parallel with the switch D_{c2}.

The IGBT portion 408 is arranged with a Vienna topology, and thus, each of the first IGBT module 416, the second IGBT module 418, and the third IGBT module 420 are arranged with a Vienna topology that include a respective diode bridge that converts an AC input voltage to a DC output voltage based on a current Iₙ, the virtual neutral of the mid-voltage connection 406, and each power phase current. In this way, the Vienna topology enables A current Iₐₙ flows (e.g., one split current of the current Iₙ) to a junction Na where the current Iₐₙ splits. One split current flows through a diode to the junction A1 and another split current flows through a diode to the junction A2. One split current, the current Iₐ₁, and the virtual neutral of the mid-voltage connection 406 combine at the junction A1 and the other split current, the current Iₐ₂, and the virtual neutral of the mid-voltage connection 406 combine at the junction A2. The combined currents flow to a junction Pa where both of the combined currents combine to form a current Iₐₚ.

Similarly, a current Ibn (e.g., one split current of the current Iₙ) flows to a junction N_{b} where the current Ibn splits. One split current flows through a diode to the junction B1 and another split current flows through a diode to the junction B2. One split current, the current I_{b1}, and the virtual neutral of the mid-voltage connection 406 combine at the junction B1 and the other split current, the current I_{B2} combine, and the virtual neutral of the mid-voltage connection 406 at the junction B2. The combined currents flow to a junction Pb where both of the combined currents combine to form a current I_{bp}.

Additionally, a current I_{cn} (e.g., one split current of the current Iₙ) flows to a junction N_{c} where the current I_{cn} splits. One split current flows through a diode to the junction C1 and another split current flows through a diode to the junction C2. One split current and the current I_{C1} combine at the junction C1 and the other split current and the current I_{C2} combine at the junction C2. Both of the combined currents flow to a junction Pc where both of the combined currents combine to form a current I_{cp}.

The currents Iₐₚ, I_{bp}, and I_{cp} combine at a junction to form a current Iₚ. A portion of the current Iₚ may be delivered to an x-ray tube of an x-ray generator as described in FIG. 1. The current Iₒ may be delivered to the x-ray tube of the x-ray generator. The current Iₚ may also flow through the capacitor C1 and capacitor C2 and combined with a portion of the current Iₚ that was not delivered to the x-ray tube of the x-ray generator. The combined current may be the current Iₙ.

In this way, the Vienna topology of the IGBT portion 408 enables the capacitor C1 and the capacitor C2 to generate between +400 V and −400 V. The voltages of the capacitor C1 and the capacitor C2 may be summed to generate 800 V. Since the capacitor C1 and capacitor C2 are electrically coupled to the mid-connection node M and thus, the mid-voltage connection 406, and the output of the IGBT portion 408, the lowest possible inductive path is desired, which may be achieved via electrically coupling the AC portion 402 and the DC portion 404 via a heat sink.

A perspective view of a side 500 of an active rectifier is illustrated in FIG. 5. The active rectifier may be an embodiment of the active rectifiers depicted in FIGS. 3 and 4. The side 500 of the active rectifier is electrically coupled to an AC source 502 to enable the AC source to deliver three phase power to the side 500, which may be an AC circuit board. The three phase power may be delivered to three AC circuit board regions of the side 500. The three AC circuit board regions may include a first AC circuit board region 504, a second AC circuit board region 506, and a third AC circuit board region 508. In this way, the three phase power may be delivered to the first AC circuit board region 504, a second AC circuit board region 506, and a third AC circuit board region 508. The second AC circuit board region 506 is positioned between the first AC circuit board region 504 and the third AC circuit board region 508.

A plurality of choke inductors may be positioned under the AC circuit board (e.g., the three AC circuit board regions) and on a top surface of the base 536 as well. A first choke inductor 538 may be positioned under the first AC circuit board region 504 and on the top surface of the base 536 at one end of the side 500. A second choke inductor 540 may be positioned under the second AC circuit board region 506 and on the top surface of the base 536 in a middle region of the side 500. A third choke inductor 542 may be positioned under the third AC circuit board region 508 and on the top surface of the base 536 at the other end of the side 500. Additionally, although not depicted here, a plurality of tee components and a plurality of inductors may be positioned under the AC circuit board (e.g., the three AC circuit board regions) and on the top surface of the base 536. A plurality of tee components and other inductors may be positioned under the AC circuit board and on the top surface of the base 536 as well. In other examples, other components may be positioned under the AC circuit board and on the top surface of the base 536 as well.

A plurality of standoffs may be positioned at various points near an edge of a base 536 of the side 500. As an example, the plurality of standoffs may include a first standoff 510, a second standoff 512, a third standoff 514, a fourth standoff 516, a fifth standoff 518, and a sixth standoff 520. In particular, two standoffs are positioned at both ends of each AC circuit board region. An enlarged view 522 of the first standoff 510 is shown. The plurality of standoffs may be hexagon male-female standoffs that are zinc electroplated.

The first standoff 510 may be positioned at one end and the second standoff 512 may be positioned at another end of the first AC circuit board region 504. In this way, power in a first phase may be transmitted from the first AC circuit board region 504 through each of the first standoff 510 and the second standoff 512 to a heat sink (not shown). The third standoff 514 may be positioned at one end of the second AC circuit board region 506 that is closest to the second standoff 512 and the fourth standoff 516 may be positioned at the other end of the second AC circuit board region 506 closest to the fifth standoff 518. Accordingly, power in a second phase may be transmitted from the second AC circuit board region 506 to each of the third standoff 514 and the fourth standoff 516 to the heat sink. The fifth standoff 518 may be positioned at one end of the third AC circuit board region 508 closest to the fourth standoff 516 and the sixth standoff 520 may be positioned at another end of the third AC circuit board region 508. Power in a third phase may be transmitted from the third AC circuit board region 508 to each of the fifth standoff 518 and the sixth standoff 520.

A plurality of couple holes may be positioned along on a side surface of the base 536 that is closest to the plurality of standoffs to couple the heat sink and the base 536. The plurality of couple holes may include a first couple hole 524, a second couple hole 526, a third couple hole 528, a fourth couple hole 530, a fifth couple hole 532, and a sixth couple hole 534. The first couple hole 524 is positioned near the first standoff 510. The second couple hole 526 is positioned near the second standoff 512. The third couple hole 528 is positioned near the third standoff 514. The fourth couple hole 530 is positioned near the fourth standoff 516. The fifth couple hole 532 is positioned near the fifth standoff 518. The sixth couple hole 534 is positioned near the sixth standoff 520.

A plurality of fasteners may extend through a plurality of through holes positioned on a surface of the heat sink through the plurality of couple holes of the side 500 to couple the heat sink and the base 536. More specifically, the plurality of through holes of the heat sink may be positioned on a surface on one side of the heat sink. In this way, one fastener may extend from one respective through hole of the heat sink through the first couple hole 524, one fastener may extend from one respective through hole positioned on the heat sink to the second couple hole 526, and one fastener may extend through one respective through hole of the heat sink to the third couple hole 528 of the side 500. Additionally, one fastener may extend from one respective through hole of the heat sink to the fourth couple hole 530, one fastener may extend from one respective through hole positioned on the heat sink to the fifth couple hole 532, and one fastener may extend from one respective through hole positioned of the heat sink to the sixth couple hole 534 of the side 500. As such, the base 536 of the side 500 may be coupled to the heat sink to achieve a configuration described in FIG. 8.

A perspective view of a side 600 of an active rectifier is illustrated in FIG. 6. The active rectifier may be an embodiment of the active rectifiers depicted in FIGS. 3 and 4. The side 600 of the active rectifier, which may be a DC circuit board, is electrically coupled to the three AC circuit board regions of side 500 depicted in FIG. 5 via a heat sink. The three phase power may be transmitted to three DC circuit board regions positioned on a top surface of a base 628 of the side 600 from the three AC circuit board regions via the heat sink. The three DC circuit board regions may include a first DC circuit board region 602, a second DC circuit board region 604, and a third DC circuit board region 606 wherein the second DC circuit board region 604 is positioned between the first DC circuit board region 602 and the third DC circuit board region 606. In this way, the three phase power delivered to the first DC circuit board region 602, the second DC circuit board region 604, and a third DC circuit board region 606 may be converted to DC power.

A plurality of inductors may be positioned under the DC circuit board (e.g., the three DC circuit board regions) and on a top surface of the base 628 as well. A first inductor 630 may be positioned under the first DC circuit board region 602 and on the top surface of the base 628 at one end of the side 600. A second inductor 632 may be positioned under the second DC circuit board region 604 and on the top surface of the base 628 in a middle region of the side 600. A third inductor 634 may be positioned under the third DC circuit board region 606 and on the top surface of the base 628 at the other end of the side 600. Additionally, although not depicted here, a plurality of tee components and a plurality of inductors may be positioned under the DC circuit board (e.g., the three DC circuit board regions) and on the top surface of the base 628. A plurality of tee components and other inductors may be positioned under the DC circuit board and on a top surface of the base 628 as well. In other examples, other components may be positioned under the DC circuit board and on the top surface of the base 628 as well.

A plurality of connecting members is positioned at various points on the side 600. Each of the connecting members extend from a side surface of the side 600 to a top surface of the side 600. In particular, one connecting member is positioned near a center of each DC circuit board region. The side 600 is electrically coupled to the heat sink via the plurality of connecting members. In an example, the plurality of connecting members may include three connecting members, such as a first connecting member 608, a second connecting member 610, and a third connecting member 612 fabricated from copper sheet metal. The first connecting member 608 is positioned near a center of the first DC circuit board region 602. The second connecting member 610 is positioned near a center of the second DC circuit board region 604. The third connecting member 612 is positioned near a center of the third DC circuit board region 606.

An enlarged view 614 of a connecting member in an uncoupled state is shown (e.g., the third connecting member 612). The uncoupled state of the connecting member may be a metal sheet configured with a plurality of angled surfaces, the plurality of angled surfaces including a first angled surface 614a with a through hole positioned near a center of the first angled surface, a second angled surface 614b that is contiguous with the first angled surface, a third angled surface 614c that is contiguous with the second angled surface, and a fourth angled surface 614d with a through hole that is contiguous with the third angled surface.

A plurality of couple holes may be positioned along on a side surface of the base 628 that is closest to the plurality of connecting members to couple the heat sink and the base 628. The plurality of couple holes may include a first couple hole 616, a second couple hole 618, a third couple hole 620, and a fourth couple hole 622. The first couple hole 616 is positioned near the first connecting member 608. The second couple hole 618 is positioned near a side of the second connecting member 610 that is closest to the first connecting member 608. The third couple hole 620 is positioned near a side of the second connecting member 610 that is closest to the third connecting member 612. The fourth couple hole 622 is positioned near the third connecting member 612.

A plurality of fasteners may extend through a plurality of through holes positioned on a surface of the heat sink through the plurality of couple holes of the side 600 to couple the heat sink and the base 628. In particular, the plurality of through holes may be positioned on a surface on another side of the heat sink, the side being different from the side of the heat sink of FIG. 5. In this way, one fastener may extend from one respective through hole of the heat sink through the first couple hole 616, one fastener may extend from one respective through hole positioned on the heat sink to the second couple hole 618, and one fastener may extend through one respective through hole of the heat sink to the third couple hole 620, and one fastener may extend from one respective through hole of the heat sink to the fourth couple hole 622 of the side 600. As such, the base 628 of the side 600 may be coupled to the heat sink to achieve a configuration described in FIG. 8.

The side 600 may also include a first resistive load 624 and a second resistive load 626. The first resistive load 624 and the second resistive load 626 may be electrically coupled to two DC capacitors (e.g., +400V/−400V) to balance the voltage between the two DC capacitors. More specifically, the first resistive load 624 may be electrically coupled to one DC capacitor and the second resistive load 626 may be electrically coupled to another DC capacitor.

FIG. 7 shows a profile view of an active rectifier 700, which may be an embodiment of the active rectifiers depicted in FIGS. 3 and 4. Elements of the active rectifier 700 that share at least some of the structural function and functional features with the active rectifiers described above in FIGS. 1 and 2 may not be reintroduced, for brevity, An AC side 702 of the active rectifier is electrically coupled to a DC side 706 via a heat sink 708, which achieves a mid-voltage connection 710 between the AC side 702 and the DC side 706. The mid-voltage connection 710 may be an embodiment of the mid-voltage connection 406 of FIG. 4. An IGBT portion 704 is positioned above a top surface of the heat sink 708 and positioned between the AC side 702 and the DC side 706. The IGBT portion integrates a Vienna topology that acts as the earth of the active rectifier 700. The AC side 702, the DC side 706, the heat sink, and other components positioned beneath the AC side and DC side function as gate drivers.

Although not depicted, the active rectifier 700 may include a controlled load with a programmable-gain amplifier (PGA) and other electrical components to lower measurements and control the active rectifier 700. The heat sink 708 is not coupled to a ground chassis of the active rectifier 700. Instead, the heat sink 708 is insulated with plastic components.

FIG. 8 shows a perspective view of an active rectifier 800, which may be an embodiment of the active rectifiers described above in FIGS. 4-7. As such, the active rectifier 800 may share at least some of the structural and functional features with the active rectifiers of FIGS. 1-3 and redundant description of these overlapping features is omitted.

Similar to FIGS. 4-7, the active rectifier 800 includes an includes a first AC circuit board region 808, a second AC circuit board region 810, and a third AC circuit board region 812 on an AC side 802 of the active rectifier, a first DC circuit board region 820, a second DC circuit board region 822, and a third DC circuit board region 824 on a DC side 804 of the active rectifier, a first IGBT circuit board 814, a second IGBT circuit board 816, and a third IGBT circuit board 818 positioned between the AC side 802 and the DC side 806, and a heat sink positioned below the first IGBT circuit board 814, the second IGBT circuit board 816, and the third IGBT circuit board 818 of an IGBT portion 804 that electrically couples the AC side and the DC side.

The first AC circuit board region 808 is spaced apart from the first DC circuit board region 820 by the first IGBT circuit board 814 at one end of the active rectifier. The second AC circuit board region 810 is spaced apart from the second DC circuit board region 822 by the second IGBT circuit board 816 in a medial region of the active rectifier 800. The third AC circuit board region 812 is spaced apart from the third DC circuit board region 824 by the third IGBT circuit board 818 at another end of the active rectifier 800. The heat sink 826 extends along the length of the first IGBT circuit board 814, the second IGBT circuit board 816, and the third IGBT circuit board 818 beneath each of the first IGBT circuit board, the second IGBT circuit board, and the third IGBT circuit board. Each IGBT module is electrically coupled to one DC region of the DC portion via a pin. Each of the AC circuit board (e.g., the three AC circuit board regions), the DC circuit board (e.g., the three DC circuit board regions), and the IGBT circuit boards includes a plurality of inductors, a plurality of capacitors, a plurality of resistors, and a plurality of sensors to measure current and voltage. For example, the AC side 802 (e.g., the AC circuit board) may include a plurality of current sensors 803 and a plurality of capacitors 805. The DC side 806 (e.g., the DC circuit board) may include a plurality of capacitors 807 and a power connector 809.

FIG. 9 shows a magnified view of an active rectifier 900, which may be an embodiment of the active rectifiers depicted in FIGS. 4-8. Elements of the active rectifier 900 that share at least some of the structural function and functional features with the active rectifiers described above in FIGS. 1-8 may not be reintroduced, for brevity.

Similar to above, the active rectifier 900 includes an AC circuit board with three AC circuit board regions on an AC side 902 of the active rectifier 900, a DC circuit board with three DC circuit boards on a DC side of the active rectifier, a heat sink 906 that is electrically coupled to the AC circuit board (e.g., the three AC circuit board regions) on one side of the heat sink and to the DC circuit board (e.g., the three DC circuit board regions) on another side of the heat sink 906, and three IGBT circuit boards that are positioned above a top surface of the heat sink 906 and positioned between the three AC circuit board regions and the three DC circuit board regions. As described herein, the AC side 902 is electrically coupled to the heat sink 906 via a plurality of standoffs, which may include six standoffs.

In an example, a first standoff 904 on one side of a first AC circuit board region (e.g., first AC circuit board region 504) may extend through the first AC circuit board region to the heat sink 906 as depicted. Similarly, a second standoff (e.g., second standoff 512) on another side of the first AC circuit board region may also extend through the first AC circuit board region to the heat sink 906, a third standoff (e.g., third standoff 514) on one side of a second AC circuit board region (e.g., second AC circuit board region 506) and a fourth standoff (e.g., fourth standoff 516) on another side of the second AC circuit board region may extend through the second AC circuit board region to the heat sink 906, and a fifth standoff (e.g., fifth standoff 518) on one side of a third AC circuit board region (e.g., third AC circuit board region 508) and a sixth standoff (e.g., sixth standoff 520) on another side of the third AC circuit board region may extend through the third AC circuit board region to the heat sink 906. In this way, each pair of the plurality of standoffs may electrically couple the first AC circuit board region, the second AC circuit board region, and the third AC circuit board region to the heat sink 906.

The first standoff 904 and the second standoff may be coupled to the first AC circuit board region via fasteners. In an example, the first standoff 904 may be coupled to the first AC circuit board region via a fastener 908. Similarly, the third standoff and the fourth standoff may be coupled to the second AC circuit board region via fasteners and the fifth standoff and the sixth standoff may be coupled to the third AC circuit board region via fasteners.

FIG. 10 shows a magnified view of a DC side 1000 of an active rectifier, which may be an embodiment of the active rectifiers depicted in FIGS. 4-9. Elements of the DC side 1000 that share at least some of the structural function and functional features with the active rectifiers described above in FIG. 6 may not be reintroduced, for brevity.

The DC side 1000 of the active rectifier includes a DC board with three DC circuit board regions including a first DC circuit board region 1002, a second DC circuit board region 1004 and a third DC circuit board region 1006. Each of the DC circuit board regions includes a connection pad and a connecting member that extends from an upper edge of a base 1022 of the DC side 1000 to the connection pad on a top surface of a respective DC circuit board region. In an example, a first connecting member 1014 extends from the upper edge of the base 1022 to a first connection pad 1008 on a top surface of the first DC circuit board region 1002. A second connecting member 1016 extends from the upper edge of the base 1022 to a second connection pad 1010 on a top surface of the second DC circuit board region 1004. A third connecting member 1018 extends from the upper edge of the base 1022 to a third connection pad 1012 on a top surface of the third DC circuit board region 1006.

An enlarged image 1020 of the first connecting member 1014 and the first connection pad is depicted. As described herein, the connecting member in an uncoupled state comprises is a metal sheet with a four angled surfaces. In an example, the first connection member has a first angled surface 1014a with a couple hole, a second angled surface 1014b, a third angled surface 1014c, and a fourth angled surface 1014d with a couple hole. In the coupled state, the first angled surface 1014a is parallel with the side of the base 1022 and is coupled to the base via a fastener near the top edge of the base and the second angled surface 1014b is nearly parallel with a top surface of the base as well as the first DC circuit board 1002, such that there is nearly a 90° angle between the first angled surface and the second angled surface.

Additionally, the third angled surface 1014c is nearly parallel with the first angled surface 1014a and the fourth angled surface 1014d is nearly parallel with the second angled surface 1014b. As such, there is nearly a 90° angle between the third angled surface and the fourth angled surface. The fourth angled surface 1014d of the first connecting member 1014 is arranged within the first connection pad 1008. The four angled surfaces of both the second connecting member 1016 and the third connecting 108 have a similar configuration which enables the fourth angled surface to be arranged within the respective connection pad. In this way, the first connecting member 1014 may electrically couple a heat sink that is in physical contact with the first angled surface of the first connecting member to the first DC circuit board region 1002.

Additionally, the second connecting member 1016 may electrically couple the heat sink that is in physical contact with the first angled surface of the second connecting member to the second DC circuit board region 1004. Similarly, the third connecting member 1018 may electrically couple the heat sink that is in physical contact with the first angled surface of the third connecting member to the third DC circuit board region 1006. As such, during operation of an x-ray generator, electricity may be conducted via the respective connecting member to enable a circuit to flow from the connecting member to the respective DC circuit board region.

The technical effect of integrating an active rectifier within an x-ray generator is that the active rectifier enables a power correction factor, which may result in increased electrical efficiency of the x-ray generator and the active rectifier may provide stabilized DC output. A stabilized DC output may allow the x-ray generator to be configured with smaller parts, which may decrease the footprint of the x-ray generator and the cost of the x-ray generator. Further, by using the heat sink as the mid-voltage connection, the number of parts utilized in the active rectifier may be reduced which may reduce the footprint and the cost of the active rectifier.

The disclosure also provides support for an active rectifier, comprising: an alternating current (AC) portion positioned on one side of the active rectifier, a direct current (DC) portion positioned on another side of the active rectifier, and an insulated gate bipolar transistor (IGBT) portion positioned on top of a heat sink that electrically couples the AC portion and the DC portion, the heat sink being positioned below the IGBT portion and between the AC portion and DC portion. In a first example of the system, the AC portion comprises a plurality of power regions populated with a plurality of power components. In a second example of the system, optionally including the first example, the IGBT portion comprises a plurality of IGBT modules. In a third example of the system, optionally including one or both of the first and second examples, the DC portion comprises a plurality of DC regions populated with a plurality of DC components.

In a fourth example of the system, optionally including one or more or each of the first through third examples, each IGBT module is electrically coupled to one DC region of the DC portion via a pin. In a fifth example of the system, optionally including one or more or each of the first through fourth examples, the AC portion is electrically coupled to a heat sink via a plurality of standoffs. In a sixth example of the system, optionally including one or more or each of the first through fifth examples, the DC portion is electrically coupled to the heat sink via a plurality of connecting members.

In a seventh example of the system, optionally including one or more or each of the first through sixth examples, an uncoupled state of a connecting member comprises a metal sheet configured with a plurality of angled surfaces, the plurality of angled surfaces including a first angled surface with a through hole positioned near a center of the first angled surface, a second angled surface that is contiguous with the first angled surface, a third angled surface that is contiguous with the second angled surface, and a fourth angled surface with a through hole that is contiguous with the third angled surface.

The disclosure also provides support for an active rectifier, comprising: an AC circuit board with three AC circuit board regions on one side of the active rectifier, a DC circuit board with three DC circuit board regions on another side of the active rectifier, a heat sink that is electrically coupled to the AC circuit board on one side of the heat sink and to the DC circuit board on another side of the heat sink, and three insulated gate bipolar transistor (IGBT) circuit boards that are positioned above a top surface of the heat sink and positioned between the AC circuit board and the DC circuit board. In a first example of the system, the three IGBT circuit boards are arranged with a Vienna topology.

In a second example of the system, optionally including the first example, two standoffs are positioned on both sides of each AC circuit board region to electrically couple the AC circuit board to the heat sink. In a third example of the system, optionally including one or both of the first and second examples, a connecting member is coupled to each DC circuit board region via fasteners arranged in through holes located at one end of the connecting member. In a fourth example of the system, optionally including one or more or each of the first through third examples, one end of the connecting member is coupled to a side surface of the heat sink via one fastener and another end of the connecting member is coupled to a connection pad on a top surface of one DC circuit board region. In a fifth example of the system, optionally including one or more or each of the first through fourth examples, the connecting member is fabricated from copper sheet metal.

The disclosure also provides support for a system, comprising: an alternating current (AC) circuit board with a first AC circuit board region, a second AC circuit board region, and a third AC circuit board region on an AC side of the active rectifier, a direct current (DC) circuit board with a first DC circuit board region, a second DC circuit board region, and a third DC circuit board region on a DC side of the active rectifier, a first insulated gate bipolar transistor (IGBT) circuit board, a second IGBT circuit board, and a third IGBT circuit board positioned between the AC side and the DC side, and a heat sink positioned below the first IGBT circuit board, the second IGBT circuit board, and the third IGBT circuit board that electrically couples the AC side and the DC side. In a first example of the system, the first AC circuit board region is spaced apart from the first DC circuit board region by the first IGBT circuit board at one end of the active rectifier.

In a second example of the system, optionally including the first example, the second AC circuit board region the spaced apart from a second DC circuit board region by the second IGBT circuit board in a medial region of the active rectifier. In a third example of the system, optionally including one or both of the first and second examples, the third AC circuit board region is spaced apart from the third DC circuit board region by the third IGBT circuit board at another end of the active rectifier. In a fourth example of the system, optionally including one or more or each of the first through third examples, the heat sink is not coupled to a ground chassis. In a fifth example of the system, optionally including one or more or each of the first through fourth examples, the heat sink is electrically coupled to the mid-voltage connection and electrically insulated from the ground chassis.

FIGS. 1-10 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another.

Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example.

As used herein, an element or step recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property. The terms “including” and “in which” are used as the plain-language equivalents of the respective terms “comprising” and “wherein.” Moreover, the terms “first,” “second,” and “third,” etc. are used merely as labels, and are not intended to impose numerical requirements or a particular positional order on their objects.

This written description uses examples to disclose the invention, including the best mode, and also to enable a person of ordinary skill in the relevant art to practice the invention, including making and using any devices or systems and performing any incorporated methods. The patentable scope of the invention is defined by the claims, and may include other examples that occur to those of ordinary skill in the art. Such other examples are intended to be within the scope of the claims if they have structural elements that do not differ from the literal language of the claims, or if they include equivalent structural elements with insubstantial differences from the literal languages of the claims.

1. An active rectifier, comprising:
an alternating current (AC) portion positioned on one side of the active rectifier;
a direct current (DC) portion positioned on another side of the active rectifier; and
an insulated gate bipolar transistor (IGBT) portion positioned on top of a heat sink that electrically couples the AC portion and the DC portion, the heat sink being positioned below the IGBT portion and between the AC portion and DC portion.

2. The active rectifier of claim 1, wherein the AC portion comprises a plurality of power regions populated with a plurality of power components.

3. The active rectifier of claim 1, wherein the IGBT portion comprises a plurality of IGBT modules.

4. The active rectifier of claim 1, wherein the DC portion comprises a plurality of DC regions populated with a plurality of DC components.

5. The active rectifier of claim 3, wherein each IGBT module is electrically coupled to one DC region of the DC portion via a pin.

6. The active rectifier of claim 1, wherein the AC portion is electrically coupled to a heat sink via a plurality of standoffs.

7. The active rectifier of claim 1, wherein the DC portion is electrically coupled to the heat sink via a plurality of connecting members.

8. The active rectifier of claim 7, wherein an uncoupled state of a connecting member comprises a metal sheet configured with a plurality of angled surfaces, the plurality of angled surfaces including a first angled surface with a through hole positioned near a center of the first angled surface, a second angled surface that is contiguous with the first angled surface, a third angled surface that is contiguous with the second angled surface, and a fourth angled surface with a through hole that is contiguous with the third angled surface.

9. An active rectifier, comprising:
an AC circuit board with three AC circuit board regions on one side of the active rectifier;
a DC circuit board with three DC circuit board regions on another side of the active rectifier;
a heat sink that is electrically coupled to the AC circuit board on one side of the heat sink and to the DC circuit board on another side of the heat sink; and
three insulated gate bipolar transistor (IGBT) circuit boards that are positioned above a top surface of the heat sink and positioned between the AC circuit board and the DC circuit board.

10. The active rectifier of claim 9, wherein the three IGBT circuit boards are arranged with a Vienna topology.

11. The active rectifier of claim 9, wherein two standoffs are positioned on both sides of each AC circuit board region to electrically couple the AC circuit board to the heat sink.

12. The active rectifier of claim 9, wherein a connecting member is coupled to each DC circuit board region via fasteners arranged in through holes located at one end of the connecting member.

13. The active rectifier of claim 12, wherein one end of the connecting member is coupled to a side surface of the heat sink via one fastener and another end of the connecting member is coupled to a connection pad on a top surface of one DC circuit board region.

14. The active rectifier of claim 13, wherein the connecting member is fabricated from copper sheet metal.

15. A system, comprising:
an alternating current (AC) circuit board with a first AC circuit board region, a second AC circuit board region, and a third AC circuit board region on an AC side of the active rectifier, a direct current (DC) circuit board with a first DC circuit board region, a second DC circuit board region, and a third DC circuit board region on a DC side of the active rectifier, a first insulated gate bipolar transistor (IGBT) circuit board, a second IGBT circuit board, and a third IGBT circuit board positioned between the AC side and the DC side, and a heat sink positioned below the first IGBT circuit board, the second IGBT circuit board, and the third IGBT circuit board that electrically couples the AC side and the DC side.

16. The system of claim 15, wherein the first AC circuit board region is spaced apart from the first DC circuit board region by the first IGBT circuit board at one end of the active rectifier.

17. The system of claim 15, wherein the second AC circuit board region the spaced apart from a second DC circuit board region by the second IGBT circuit board in a medial region of the active rectifier.

18. The system of claim 15, wherein the third AC circuit board region is spaced apart from the third DC circuit board region by the third IGBT circuit board at another end of the active rectifier.

19. The system of claim 15, wherein the heat sink is not coupled to a ground chassis.

20. The system of claim 15, wherein the heat sink is electrically coupled to the mid-voltage connection and electrically insulated from the ground chassis.
